(19) United States
(12) Patent Application Publication
(10) Pub. No.: US 2020/0117594 A1
(43) Pub. Date: Apr. 16, 2020

(54) IMPLEMENTING LOW COST AND LARGE CAPACITY DRAM-BASED MEMORY MODULES

(71) Applicant: ScaleFlux, Inc., San Jose, CA (US)

(72) Inventors: Tong Zhang, Albany, NY (US); Yang Liu, Milpitas, CA (US); Fei Sun, Irvine, CA (US); Hao Zhong, Los Gatos, CA (US)

(21) Appl. No.: 16/596,876

(22) Filed: Oct. 9, 2019

Related U.S. Application Data
(60) Provisional application No. 62/743,654, filed on Oct. 10, 2018.

(51) Int. Cl. G06F 12/02; G11C 5/04; G06F 3/06; G06F 11/10; G11C 11/4096

(52) U.S. Cl. CPC G06F 12/0253; G11C 5/04; G06F 2212/70; G06F 11/1016; G11C 11/4096; G06F 3/0619

(57) ABSTRACT

A heterogeneous dynamic random access memory (DRAM) module, including: a first set of DRAM chips; a second set of DRAM chips, wherein the DRAM chips in the second set of DRAM chips have a lower storage reliability than the DRAM chips in the first set of DRAM chips; and a controller coupled to the first and second sets of DRAM chips, wherein the controller includes a DRAM access engine for accessing the second set of DRAM chips and for ensuring a data storage integrity of the second set of DRAM chips.

### TECHNICAL FIELD

The present disclosure relates to the field of solid-state memory, and particularly to realizing low cost and large capacity memory systems in computers.

### BACKGROUND

Motivated by recent progress in new non-volatile memory (NVM) technologies (e.g., 3DXP, phase-change memory, STT-RAM, and ReRAM), there has been a high hope of innovating the memory and storage hierarchy in future computing systems. Since none of the NVM technologies can achieve the same high-speed performance as existing DRAM (i.e., the access latency of NVM technologies is at least several times longer than that of DRAM), there is consensus that NVM can only complement DRAM instead of replacing DRAM. To facilitate the real-life adoption of NVM technologies, the industry has been developing specifications to standardize the interface between CPUs and NVM chips. For example, the JEDEC Solid State Technology Association is in the process of developing a so-called NVDIMM-P standard, which specifies the interface protocol between CPUs and NVDIMM-P modules. Each NVDIMM-P module contains both DRAM and NVM chips, and has the same form factor as a conventional DIMM module. CPUs can access the DRAM chips on each NVDIMM-P module through a deterministic-latency byte-addressable interface (e.g., today's DDR4 interface). CPUs can access the NVM chips on each NVDIMM-P module through a new interface being standardized by JEDEC. Because the access latency of NVM chips may vary (e.g., due to the different operational characteristics of different NVM technologies, and the use of more sophisticated management and error correction for NVM chips), the new interface for the NVM chips on each NVDIMM-P module can support non-deterministic access latency.

Although NVM technologies support non-volatile data storage that is absent from DRAM, current interest on NVM technologies has been mainly driven by the promise that future NVM chips will have a significantly lower bit cost than DRAM chips. In fact, many real-life applications (e.g., in-memory database) are essentially constrained by the memory bit cost, and do not necessarily care whether the memory is volatile (like DRAM) or non-volatile. Compared with DRAM, all the NVM technologies not only suffer from (much) longer access latency but also suffer from (much) worse write endurance, which could make it a non-trivial task for computing systems to most effectively and safely use NVM chips (e.g., on future NVDIMM-P modules).

### SUMMARY

Accordingly, embodiments of the present disclosure are directed to a method for implementing DRAM-based memory modules that provide low-cost and high-speed large-capacity memory in computing systems.

A first aspect of the disclosure is directed to a heterogeneous dynamic random access memory (DRAM) module, including: a first set of DRAM chips; a second set of DRAM chips, wherein the DRAM chips in the second set of DRAM chips have a lower storage reliability than the DRAM chips in the first set of DRAM chips; and a controller coupled to the first and second sets of DRAM chips, wherein the controller includes a DRAM access engine for accessing the second set of DRAM chips and for ensuring a data storage integrity of the second set of DRAM chips.

A second aspect of the disclosure is directed to method for accessing a heterogeneous dynamic random access memory (DRAM) module, the DRAM module including first and second sets of DRAM chips, wherein the DRAM chips in the second set of DRAM chips have a lower storage reliability than the DRAM chips in the first set of DRAM chips, including: upon receipt of a write request including a PBA set to store data in the second set of DRAM chips: determining whether the write request entirely covers at least one PBA in the PBA set; partitioning the PBA set into a first PBA set and a second PBA set, wherein each PBA in the first PBA set is entirely covered by the write request and wherein each PBA in the second PBA set is not entirely covered by the write request; reading data from each PBA in the second PBA set and performing error correction coding (ECC) decoding on the data; combining the decoded data with the write request to form a new set of data; performing ECC encoding on the new set of data to obtain a set of ECC codewords; and writing the set of ECC codewords to the PBAs in the PBA set.

A third aspect of the disclosure is directed to a method for accessing a heterogeneous dynamic random access memory (DRAM) module, the DRAM module including first and second sets of DRAM chips, wherein the DRAM chips in the second set of DRAM chips have a lower storage reliability than the DRAM chips in the first set of DRAM chips, including: upon receipt of a read request including a byte address set for data in the second set of DRAM chips: deriving a logical block address (LBA) set containing consecutive LBAs fully covering the byte address set; determining, based on the LBA set, physical locations and lengths of a set of corresponding compressed data blocks in the second set of DRAM chips; deriving a PBA set that covers all the compressed data blocks; and determining, using a PBA-PBA mapping table, whether any PBAs in the PBA set correspond to a bad physical block.

A fourth aspect of the disclosure is directed to a method for accessing a heterogeneous dynamic random access memory (DRAM) module, the DRAM module including first and second sets of DRAM chips, wherein the DRAM chips in the second set of DRAM chips have a lower storage reliability than the DRAM chips in the first set of DRAM chips, including: upon receipt of a read request including a byte address set for data in the second set of DRAM chips: deriving an LBA set containing consecutive LBAs fully covering the byte address set; partitioning the LBA set into a first LBA set and a second LBA set, wherein each LBA in the first LBA set is entirely covered by the write request and wherein each LBA in the second LBA set is not entirely covered by the write request; reading all compressed data blocks associated with the LBAs in the second LBA set and performing ECC decoding and decompression to obtain decoded data; combining the decoded data with the write request to form a new set of data; carrying out compression and error correction coding (ECC) encoding on the new set of data to obtain compressed data blocks; choosing a segment having enough space to store the compressed data blocks; deriving a PBA set in the chosen segment that will cover the compressed data blocks; and determining whether any PBA in the PBA set corresponds to a bad physical block.

### BRIEF DESCRIPTION OF THE DRAWINGS

The numerous advantages of the present disclosure may be better understood by those skilled in the art by reference to the accompanying figures.

FIG. 1 illustrates the architecture of a heterogeneous DRAM module including high-reliability DRAM and low-reliability DRAM according to embodiments.

FIG. 2 illustrates the architecture of a controller on a heterogeneous DRAM module according to embodiments.

FIG. 3 illustrates an PBA-PBA mapping table according to embodiments.

FIG. 4 illustrates an operational flow diagram of a low-reliability DRAM access engine realizing byte-address-to-PBA mapping according to embodiments.

FIG. 5 illustrates an operational flow diagram of the low-reliability DRAM access engine choosing one PBA set P_{b} to serve a read or write request according to embodiments.

FIG. 6 illustrates low-reliability DRAM space usage when using transparent data compression according to embodiments.

FIG. 7 illustrates an address mapping table when using transparent data compression on the low-reliability DRAM according to embodiments.

FIG. 8 illustrates an operational flow diagram of the low-reliability DRAM access engine serving a read request transparent data compression according to embodiments.

FIG. 9 illustrates an operational flow diagram of the low-reliability DRAM access engine serving a write request according to embodiments.

FIG. 10 illustrates an operational flow diagram of a background garbage collection process according to embodiments.

### DETAILED DESCRIPTION

Reference will now be made in detail to embodiments of the disclosure, examples of which are illustrated in the accompanying drawings.

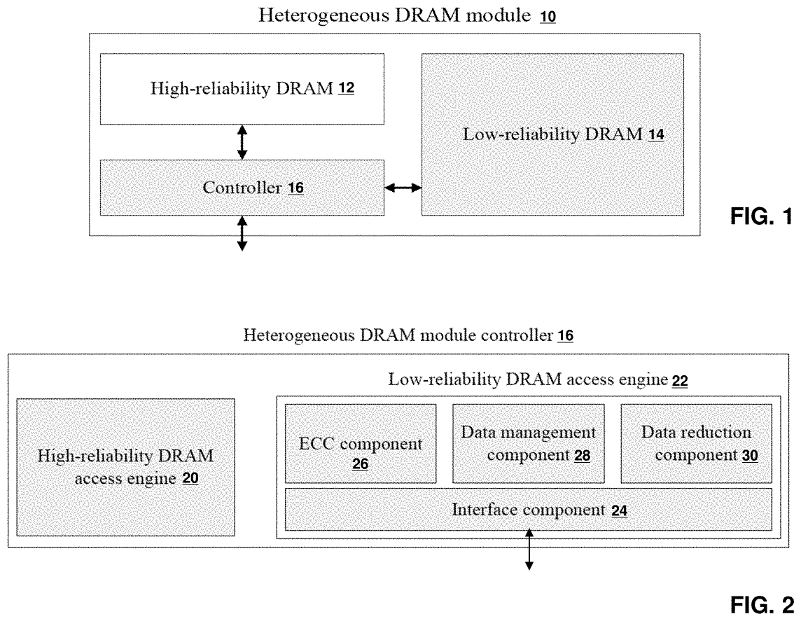

FIG. 1 illustrates the architecture of a heterogeneous DRAM module 10 (hereafter referred to as DRAM module 10) that contains both a set of high-reliability dynamic random-access memory (DRAM) chips 12 (hereafter high-reliability DRAM 12) and a set of low-reliability DRAM chips 14 (hereafter low-reliability DRAM 14). The high-reliability DRAM 12 have the same very high data storage reliability as conventional DRAM chips being used in today's computing systems. In comparison, the low-reliability DRAM 14 are subject to much worse storage reliability (i.e., very high bit error probability) and may contain a large number of un-repairable defects (e.g., defective memory cells, wordlines, and bitlines). A controller 16 is responsible for accessing the high-reliability DRAM 12 and low-reliability DRAM 14 on the DRAM module 10 and interfacing with a CPU (e.g., a host computing system) through a memory interface 24 (FIG. 2). The DRAM module 10 may use the same form factor (e.g., the DIMM form factor) as conventional DRAM modules.

When a CPU accesses the high-reliability DRAM 12 on the DRAM module 10, the CPU simply uses existing deterministic-latency DRAM access protocol standards (e.g., DDR4) to communicate with the controller 16 on the DRAM module 10. When a CPU accesses the low-reliability DRAM 14 on the DRAM module 10, the CPU must use a new interface standard (e.g., JEDEC NVDIMM-P) to communicate with the controller 16 on the DRAM module 10. The latency for a CPU to access the low-reliability DRAM 14 can be either deterministic or non-deterministic. The controller 16 on the DRAM module 10 carries out data management, error correction, and/or other necessary operations to ensure the data storage integrity of the low-reliability DRAM 14.

FIG. 2 illustrates the architecture of the controller 16 on the DRAM module 10 according to embodiments. As shown, the controller 10 may include two data access engines, a high-reliability access engine 20 and a low-reliability DRAM access engine 22. The high-reliability DRAM access engine 20 is responsible for accessing the high-reliability DRAM 12 and supports conventional deterministic-latency DRAM access protocol such as DDR4. The low-reliability DRAM access engine 22 is responsible for accessing the low-reliability DRAM 14 and supports new access protocol (with latency of being either deterministic or non-deterministic) such as the one specified by the JEDEC NVDIMM-P standard. The low-reliability DRAM access engine 22 may include several components that collectively ensure the data storage integrity of the low-reliability DRAM 14, implement necessary data management functions, and even realize data reduction to further reduce the effective bit cost of the low-reliability DRAM 14.

As illustrated in FIG. 2, the low-reliability DRAM access engine 22 may include (1) an interface component 24 that communicates with CPUs, (2) an error correction coding (ECC) component 26 that carries out ECC encoding and decoding operations, (3) a data management component 28 that performs management operations to support data read/write access to the low-reliability DRAM 14, and (4) a data reduction component 30 that carries out transparent data compression/decompression operations in order to reduce the read/write latency and effective bit cost of the low-reliability DRAM 14. In the following, the architecture of the low-reliability DRAM access engine 22 with and without implementing transparent data compression is presented.

First, the low-reliability DRAM access engine 22 when it does not implement transparent data compression is presented. In this case, the low-reliability DRAM access engine 22 uses the same ECC (provided by ECC component 26) to protect all the user data in the low-reliability DRAM 14, i.e., all the ECC codewords have the same length and same error-correction strength.

Let nₑ denote the amount of user data (e.g., 256-byte, 2 k-byte) being protected by one ECC codeword. The low-reliability DRAM access engine 22 partitions the storage space in the low-reliability DRAM 14 into an array of consecutive physical blocks, where each block is assigned with a physical page address (PBA) and protected by one ECC codeword. Hence, each block can store size-nₑ user data. A CPU accesses the low-reliability DRAM 14 in a byte-addressable manner (i.e., the CPU sends the starting byte address and length of the data being accessed). Let A_{b} denote the set of consecutive byte addresses of the data being accessed by a CPU. The low-reliability DRAM access engine 22 uses a fixed mapping function f(L) to determine the byte-address-to-PBA mapping, i.e., given the byte address set A_{b}, its corresponding PBA set P_{b} can be obtained as P_{b}=f(A_{b}), where the PBA set P_{b} contains one or multiple consecutive PBAs that fully cover the data being accessed by the CPU. As a result, the low-reliability DRAM access engine 22 does not need to explicitly store any byte-address-to-PBA mapping information. However, the low-reliability DRAM 14 may likely have a certain amount of bad physical blocks that contain too many defective DRAM cells to be handled by the ECC component 26 (i.e., the ECC component 26 cannot guarantee the storage integrity of bad physical blocks).

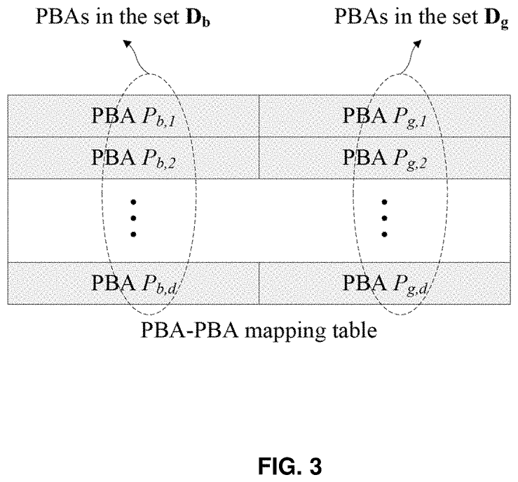

Let D_{b} denote the set that contains the PBAs of all the bad physical blocks in the low-reliability DRAM 14. Assume the set D_{b} contains a total of d bad physical blocks. The low-reliability DRAM access engine 22 allocates d good physical blocks as a replacement for the d bad physical blocks, and let the set D_{g} denote the set that contains the d allocated good physical blocks. The low-reliability DRAM access engine 22 maintains a PBA-PBA mapping table (as illustrated in FIG. 3) that maps each bad block in the set D_{b} to one unique good block in the set D_{g}. The PBA-PBA mapping table is indexed by the PBAs in the set D_{b}.

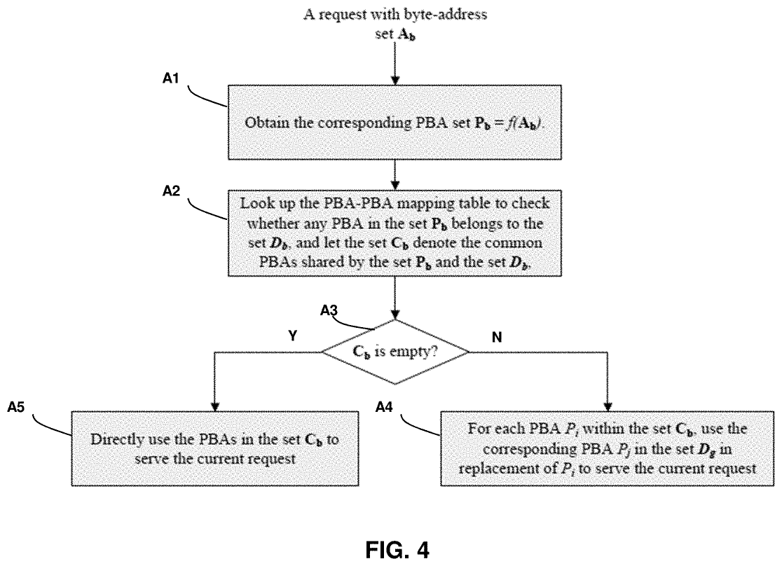

FIG. 4 illustrates an operational flow diagram of the low-reliability DRAM access engine 22 realizing byte-address-to-PBA mapping. At process A1, upon receiving a read or write request from a CPU with the byte-address set A_{b}, the corresponding PBA set P_{b} is obtained according to P_{b}=f(A_{b}). At process A2, a look-up is performed in the PBA-PBA mapping table to determine whether any PBA in the set P_{b} belongs to the set D_{b} (i.e., corresponds to one or multiple entries in the PBA-PBA mapping table that map from the set D_{b} to the set D_{g}). Let the PBA set C_{b}denote the common PBAs shared by the set P_{b} and the set D_{b}, i.e., C_{b}=P_{b}∩D_{b}. If the set C_{b} is not empty (i.e., C_{b}≢Ø) (N at process A3), then at process A4, for each PBA Pᵢ within the set C_{b}, the corresponding PBA Pⱼ in the set D_{g} is used in replacement of Pᵢ to serve the current request. Otherwise, if the set C_{b} is empty (i.e., C_{b}=Ø) (Y at process A3), at process A5, the PBAs in the set P_{b} are directly used to serve the current request.

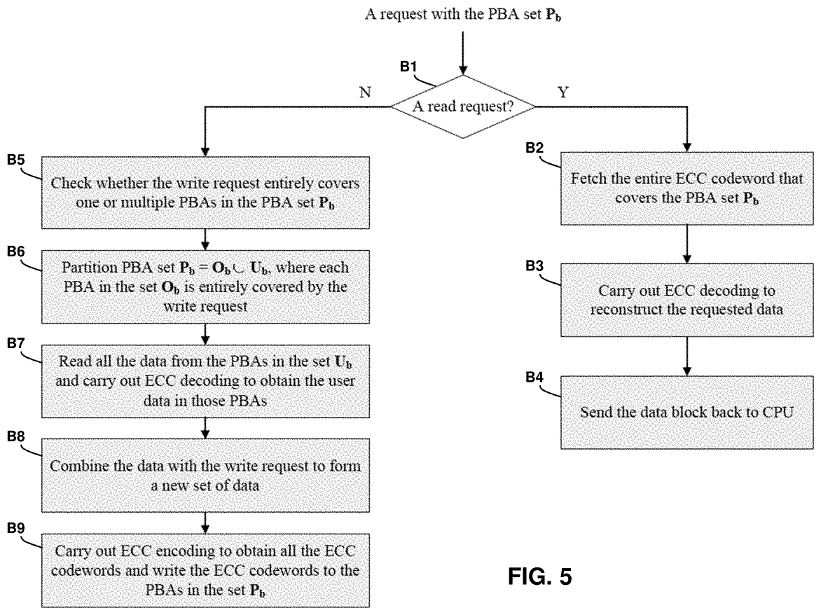

FIG. 5 further illustrates the operational flow diagram when the low-reliability DRAM access engine 22 has chosen the PBA set P_{b} to serve a read or write request. If it is a read request (Y at process B1), then the ECC codeword(s) that cover the PBA set P_{b} are fetched at process B2, ECC decoding is carried out on the ECC codeword(s) at process B3 to reconstruct the requested data, and the data is sent back to the CPU at process B4.

If it is a write request (N at process B1), as further illustrated in FIG. 5, a check is made at process B5 to determine whether the write request entirely covers one or multiple PBAs in the PBA set P_{b}. At process B6, the PBA set P_{b} is partitioned as P_{b}=O_{b}∪U_{b}, where each PBA in the set O_{b} is entirely covered by the write request and each PBA in the set U_{b} is not entirely covered by the write request. At process B7, all the data from the PBAs in the set U_{b} is read and ECC decoding is carried out to obtain the user data in those PBAs. At process B8, the data is combined with the write request to form a new set of data that should be stored in the PBAs in the set P_{b}. At process B9, ECC encoding is carried out to obtain all the ECC codewords, and the ECC codewords are written to the PBAs in the set P_{b}.

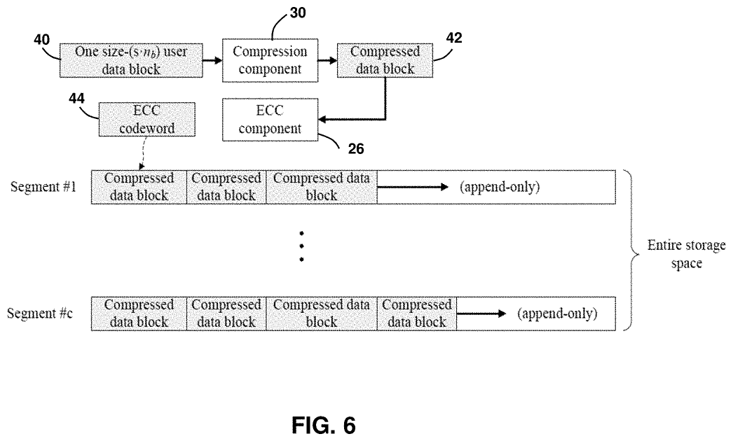

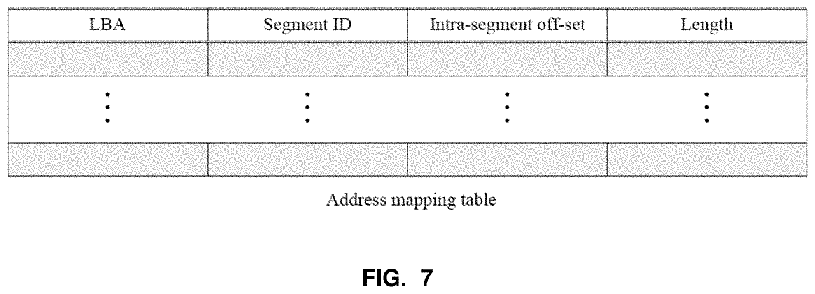

The low-reliability DRAM access engine 22 when it implements transparent data compression will now be described. The low-reliability DRAM access engine 22 applies data compression to reduce the effective bit cost and read/write latency of the low-reliability DRAM 14. Let n_{b} denote the typical DRAM access unit (e.g., 32-byte or 64-byte) being used by a CPU on each DRAM module 10. The low-reliability DRAM access engine 22 partitions the address space into an array of consecutive logical blocks, where each logical block is assigned a logical block address (LBA) and spans over the storage space of s⋅n_{b}, where s≥1 is an integer. As depicted in FIG. 6, the data reduction component 30 of the low-reliability DRAM access engine 22 compresses each individual size-(s⋅n_{b}) user data block 40 at one LBA, independent from other user data. Each compressed data block 42 is protected by one ECC codeword 44 via the ECC component 26. Since different compressed data blocks 42 may have different sizes, different ECC codewords 44 may have different sizes as well. As further illustrated in FIG. 6, the low-reliability DRAM access engine 22 partitions the entire storage space of the low-reliability DRAM 14 into c>1 segments, and writes compressed data blocks 42 into each segment in an append-only manner. As illustrated in FIG. 7, the low-reliability DRAM access engine 22 maintains a mapping table that maps each LBA to the physical location of its corresponding compressed data block. In the mapping table, each entry is indexed by the LBA and contains the physical location (i.e., the segment ID and intra-segment off-set) and the length of the compressed data block.

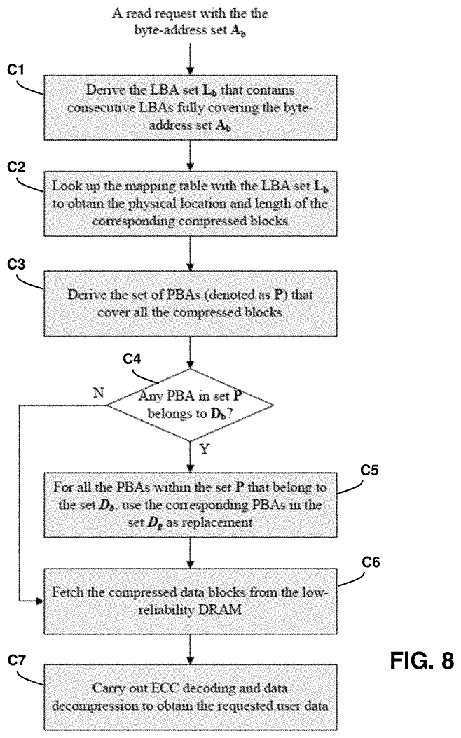

FIG. 8 illustrates an operational flow diagram when the low-reliability DRAM access engine 22 serves a read request from a CPU with the byte-address set A_{b} (the set A_{b} contains the consecutive byte addresses covered by the read request). Given the byte-address set A_{b}, at process C1, a LBA set L_{b} is derived that contains consecutive LBAs fully covering the byte-address set A_{b}. At process C2, the mapping table with the LBA set L_{b} is examined to obtain the physical location and length of the corresponding compressed data blocks. At process C3, the set of PBAs (denoted as P) that cover all the compressed data blocks is derived. If any PBA within the set P belongs to the set D_{b} (i.e., corresponds to one entry in the PBA-PBA mapping table that maps from the set D_{b} to the set D_{g}) (Y at process C4), for all the PBAs within the set P that belong to the set D_{b}, the corresponding PBAs in the set D_{g} are used as replacements at process C5. Otherwise (N at process C4), flow passes to process C6. At process C6, the low-reliability DRAM access engine 22 fetches the compressed data blocks from the low-reliability DRAM 14, and at process C7, carries out ECC decoding and data decompression to obtain the requested user data from the compressed data blocks.

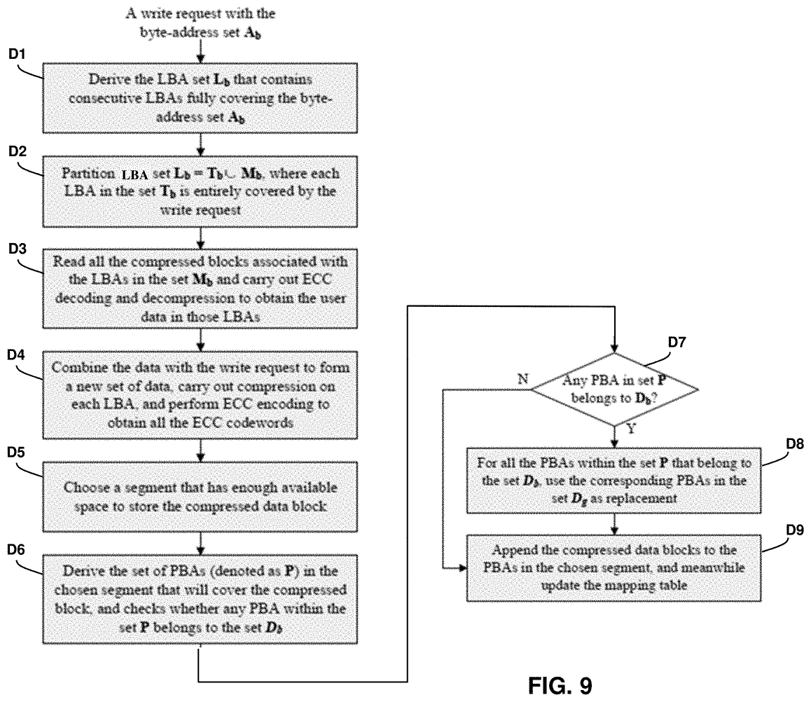

FIG. 9 illustrates an operational flow diagram when the low-reliability DRAM access engine 22 serves a write request from a CPU with the byte-address set A_{b} (the set A_{b} contains the consecutive byte addresses covered by the read request). Given the byte-address set A_{b}, at process D1, an LBA set L_{b} that contains consecutive LBAs fully covering the byte-address set A_{b} is derived. At process D2, the LBA set L_{b} is portioned as L_{b}=T_{b}∪M_{b}, where each LBA in the set T_{b} is entirely covered by the write request and each LBA in the set M_{b} is not entirely covered by the write request. At process D3, all of the compressed data blocks associated with the LBAs in the set M_{b} are read, and ECC decoding and decompression are carried out to obtain the user data in those LBAs.

At process D4, the data is combined with the write request to form a new set of data that should be stored in the LBAs in the set L_{b}, compression on each LBA is carried out, and ECC encoding is performed to obtain compressed data blocks. At process D5, a segment is chosen that has enough available space to store the compressed data blocks. At process D6, the set of PBAs (denoted as P) in the chosen segment that will cover the compressed data blocks is derived, and a check is made to determine whether any PBA within the set P belongs to the set D_{b} (i.e., corresponds to one entry in the PBA-PBA mapping table that maps from the set D_{b} to the set D_{g}). For all the PBAs within the set P that belong to the set D_{b} (Y at process D7), corresponding PBAs in the set D_{g} are used as replacements at process D8. At process D9, the low-reliability DRAM access engine 22 appends the compressed data blocks to the PBAs in the chosen segment and updates the mapping table.

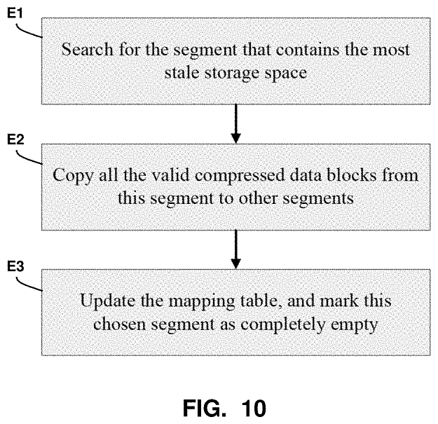

Since the low-reliability DRAM access engine 22 writes all the segments of the low-reliability DRAM 14 in the append-only manner, it must periodically carry out a garbage collection process in the background to reclaim the stale storage space in one segment. FIG. 10 illustrates an operational flow diagram of a background garbage collection process. At process E1, a search is performed to identify the segment that contains the most stale storage space. At process E2, all of the valid compressed data blocks from this segment are copied to other segments. At process E3, the mapping table is updated and the chosen segment is marked as completely empty.

It is understood that aspects of the present disclosure may be implemented in any manner, e.g., as a software program, or an integrated circuit board or a controller card that includes a processing core, I/O and processing logic. Aspects may be implemented in hardware or software, or a combination thereof. For example, aspects of the processing logic may be implemented using field programmable gate arrays (FPGAs), ASIC devices, or other hardware-oriented system.

Aspects may be implemented with a computer program product stored on a computer readable storage medium. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, etc. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Java, Python, Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

The computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. The computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by hardware and/or computer readable program instructions.

The flowchart and block diagrams in the figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The foregoing description of various aspects of the present disclosure has been presented for purposes of illustration and description. It is not intended to be exhaustive or to limit the concepts disclosed herein to the precise form disclosed, and obviously, many modifications and variations are possible. Such modifications and variations that may be apparent to an individual in the art are included within the scope of the present disclosure as defined by the accompanying claims.

1. A heterogeneous dynamic random access memory (DRAM) module, comprising:
a first set of DRAM chips;
a second set of DRAM chips, wherein the DRAM chips in the second set of DRAM chips have a lower storage reliability than the DRAM chips in the first set of DRAM chips; and
a controller coupled to the first and second sets of DRAM chips, wherein the controller includes a DRAM access engine for accessing the second set of DRAM chips and for ensuring a data storage integrity of the second set of DRAM chips.

2. The heterogeneous DRAM module according to claim 1, wherein upon receipt of a read request from, or a write request to, the second set of DRAM chips, the request including a byte address set, the DRAM access engine is configured to:
determine a byte address to physical block address (PBA) mapping to obtain a PBA set corresponding to the byte address set;
determine, using a PBA-PBA mapping table, whether any PBA in the PBA set correspond to a bad physical block;
serve the read or write request with the PBA set if the PBA set does not include any PBAs corresponding to a bad physical block; and
for each PBA in the PBA set that corresponds to a bad physical block, replace that PBA with another PBA to form a new PBA set to serve the read or write request.

3. The heterogeneous DRAM module according to claim 1, wherein upon receipt of a read request including a PBA set, the DRAM access engine is configured to:
fetch error correction coding (ECC) codewords that cover the PBA set from the second set of DRAM chips; and
perform ECC decoding on the ECC codewords to obtain data associated with the read request.

4. The heterogeneous DRAM module according to claim 1, wherein upon receipt of a write request with a PBA set to the second set of DRAM chips, the DRAM access engine is configured to:
determine whether the write request entirely covers at least one PBA in the PBA set;
partition the PBA set into a first PBA set and a second PBA set, wherein each PBA in the first PBA set is entirely covered by the write request and wherein each PBA in the second PBA set is not entirely covered by the write request;
read data from each PBA in the second PBA set and perform ECC decoding on the data;
combine the decoded data with the write request to form a new set of data;
carry out ECC encoding on the new set of data to obtain a set of ECC codewords; and
write the set of ECC codewords to the PBAs in the PBA set.

5. The heterogeneous DRAM module according to claim 1, wherein upon receipt of a read request with a byte address set, the DRAM access engine is configured to:
derive a logical block address (LBA) set containing consecutive LBAs fully covering the byte address set;
determine, based on the LBA set, physical locations and lengths of a set of corresponding compressed data blocks in the second set of DRAM chips;
derive a PBA set that covers all the compressed data blocks; and
determine, using a PBA-PBA mapping table, whether any PBAs in the PBA set correspond to a bad physical block.

6. The heterogeneous DRAM module according to claim 5, wherein the DRAM access engine is further configured to:
fetch the set of compressed data blocks from the second set of DRAM chips if the PBA set does not include any PBAs corresponding to a bad physical block; and
carry out ECC decoding and data decompression on the set of compressed data blocks.

7. The heterogeneous DRAM module according to claim 5, wherein the DRAM access engine is further configured to:
for each PBA in the PBA set that corresponds to a bad physical block, replace that PBA with another PBA to form a new PBA set; and
fetch a set of compressed data blocks based on the new PBA set, and carry out ECC decoding and data decompression on the set of compressed data blocks.

8. The heterogeneous DRAM module according to claim 1, wherein upon receipt of a write request with a byte address set to the second set of DRAM chips, the DRAM access engine is configured to:
derive an LBA set containing consecutive LBAs fully covering the byte address set;
partition the LBA set into a first LBA set and a second LBA set, wherein each LBA in the first LBA set is entirely covered by the write request and wherein each LBA in the second LBA set is not entirely covered by the write request;
read all compressed data blocks associated with the LBAs in the second LBA set and perform ECC decoding and decompression to obtain decoded data;
combine the decoded data with the write request to form a new set of data;
carry out compression and ECC encoding on the new set of data to obtain compressed data blocks;
choose a segment having enough space to store the compressed data blocks;
derive a PBA set in the chosen segment that will cover the compressed data blocks; and
determine whether any PBA in the PBA set corresponds to a bad physical block.

9. The heterogeneous DRAM module according to claim 8, wherein the DRAM access engine is further configured to:
for each PBA in the PBA set that corresponds to a bad physical block, replace that PBA with another PBA;
append the compressed data blocks to PBAs in the chosen segment; and
update a mapping table that maps each LBA to a physical location of its corresponding compressed data block.

10. The heterogeneous DRAM module according to claim 8, wherein, if the PBA set does not include any PBAs corresponding to a bad physical block, the DRAM access engine is further configured to:
append the compressed data blocks to PBAs in the chosen segment; and
update a mapping table that maps each LBA to a physical location of its corresponding compressed data block.

11. The heterogeneous DRAM module according to claim 1, wherein the DRAM access engine further comprises:
an ECC component for performing ECC coding and decoding;
a data management component for supporting read/write access; and
a data compression/decompression component for providing transparent data compression/decompression operations.

12. A method for accessing a heterogeneous dynamic random access memory (DRAM) module, the DRAM module including first and second sets of DRAM chips, wherein the DRAM chips in the second set of DRAM chips have a lower storage reliability than the DRAM chips in the first set of DRAM chips, comprising:
upon receipt of a write request including a PBA set to store data in the second set of DRAM chips:
determining whether the write request entirely covers at least one PBA in the PBA set;
partitioning the PBA set into a first PBA set and a second PBA set, wherein each PBA in the first PBA set is entirely covered by the write request and wherein each PBA in the second PBA set is not entirely covered by the write request;
reading data from each PBA in the second PBA set and performing error correction coding (ECC) decoding on the data;
combining the decoded data with the write request to form a new set of data;
performing ECC encoding on the new set of data to obtain a set of ECC codewords; and
writing the set of ECC codewords to the PBAs in the PBA set.

13. The method according to claim 12, further comprising:
upon receipt of a read request including a PBA set for data in the second set of DRAM chips:
fetching ECC codewords that cover the PBA set from the second set of DRAM chips; and
performing ECC decoding on the ECC codewords to obtain data associated with the read request;

14. A method for accessing a heterogeneous dynamic random access memory (DRAM) module, the DRAM module including first and second sets of DRAM chips, wherein the DRAM chips in the second set of DRAM chips have a lower storage reliability than the DRAM chips in the first set of DRAM chips, comprising:
upon receipt of a read request including a byte address set for data in the second set of DRAM chips:
deriving a logical block address (LBA) set containing consecutive LBAs fully covering the byte address set;
determining, based on the LBA set, physical locations and lengths of a set of corresponding compressed data blocks in the second set of DRAM chips;
deriving a PBA set that covers all the compressed data blocks; and
determining, using a PBA-PBA mapping table, whether any PBAs in the PBA set correspond to a bad physical block.

15. The method according to claim 14, further comprising:
fetching the set of compressed data blocks from the second set of DRAM chips if the PBA set does not include any PBAs corresponding to a bad physical block; and
carrying out error correction coding (ECC) decoding and data decompression on the set of compressed data blocks.

16. The method according to claim 14, further comprising:
for each PBA in the PBA set that corresponds to a bad physical block, replacing that PBA with another PBA to form a new PBA set;
fetching a set of compressed data blocks based on the new PBA set: and
carrying out ECC decoding and data decompression on the set of compressed data blocks.

17. A method for accessing a heterogeneous dynamic random access memory (DRAM) module, the DRAM module including first and second sets of DRAM chips, wherein the DRAM chips in the second set of DRAM chips have a lower storage reliability than the DRAM chips in the first set of DRAM chips, comprising:
upon receipt of a read request including a byte address set for data in the second set of DRAM chips:
deriving an LBA set containing consecutive LBAs fully covering the byte address set;
partitioning the LBA set into a first LBA set and a second LBA set, wherein each LBA in the first LBA set is entirely covered by the write request and wherein each LBA in the second LBA set is not entirely covered by the write request;
reading all compressed data blocks associated with the LBAs in the second LBA set and performing ECC decoding and decompression to obtain decoded data;
combining the decoded data with the write request to form a new set of data;
carrying out compression and error correction coding (ECC) encoding on the new set of data to obtain compressed data blocks;
choosing a segment having enough space to store the compressed data blocks;
deriving a PBA set in the chosen segment that will cover the compressed data blocks; and
determining whether any PBA in the PBA set corresponds to a bad physical block.

18. The method according to claim 17, further comprising:
for each PBA in the PBA set that corresponds to a bad physical block, replacing that PBA with another PBA;
appending the compressed data blocks to PBAs in the chosen segment; and
updating a mapping table that maps each LBA to a physical location of its corresponding compressed data block.

19. The method according to claim 17, wherein, if the PBA set does not include any PBAs corresponding to a bad physical block, the method further comprises:
appending the compressed data blocks to PBAs in the chosen segment; and
updating a mapping table that maps each LBA to a physical location of its corresponding compressed data block.
